(19) United States
(12) Patent Application Publication
(10) Pub. No.: US 2015/0206602 A1
(43) Pub. Date: Jul. 23, 2015

(54) CHIP, OPERATION METHOD, AND MANUFACTURING METHOD OF ELECTRONIC APPARATUS

(71) Applicant: Nuvoton Technology Corporation, Hsinchu (TW)

(72) Inventor: Jing-Shiang Tseng, Hsinchu (TW)

(21) Appl. No.: 14/475,584

(22) Filed: Sep. 3, 2014

(30) Foreign Application Priority Data
Jan. 17, 2014 (TW) 103101701

(51) Int. Cl. G11C 29/44; H01L 21/66

(52) U.S. Cl. CPC G11C 29/44; H01L 22/10; G11C 2029/0403

(57) ABSTRACT

A chip, including a processing unit, a non-volatile memory, a bus unit, and a capture unit, is provided. The processing unit is configured to execute a process. The capture unit is coupled to the non-volatile memory, the processing unit, and the bus unit, and captures a process execution history of the process from the bus unit and stores the process execution history in the non-volatile memory.

### CROSS-REFERENCE TO RELATED APPLICATION

This application claims the priority benefit of Taiwan application serial no. 103101701, filed on Jan. 17, 2014. The entirety of the above-mentioned patent application is hereby incorporated by reference herein and made a part of this specification.

### BACKGROUND OF THE INVENTION

1. Field of the Invention

The embodiments of the invention relates to a chip, an operation method, and a manufacturing method of an electronic apparatus.

2. Description of Related Art

Semiconductor testing for integrated circuit (IC) chips is a necessary process at different stages of semiconductor manufacture. Every IC chip in wafer and package configurations must be tested to ensure its electrical function. For example, new chip design or improvement of unit production may have demand for testing of products. Along with the enhancement and complication of chip functions, high-speed and precise testing becomes more and more important.

Generally, in the manufacturing process of IC chips, a specific test program is loaded to a test machine for the test machine to perform basic tests on the chips, so as to determine whether the chips can operate normally. However, as IC chips become more powerful and have more complicated structures, it becomes difficult for the test program to correctly judge the quality of the IC chips.

### SUMMARY OF THE INVENTION

The chip in an embodiment of the invention includes a processing unit, a non-volatile memory, a bus unit, and a capture unit. The processing unit is configured to execute a process. The capture unit is coupled to the non-volatile memory, the processing unit, and the bus unit, and captures a process execution history of the process from the bus unit and stores the process execution history in the non-volatile memory.

The operation method in an embodiment of the invention includes the following steps. A first apparatus is provided, wherein the first apparatus includes a first non-volatile memory. The first apparatus is used to execute a process. A first process execution history corresponding to the process is stored in the first non-volatile memory. A second apparatus is provided, wherein the second apparatus includes a second non-volatile memory. The second apparatus is used to execute the process. A second process execution history corresponding to the process is stored in the second non-volatile memory. The first process execution history and the second process execution history are compared to obtain a difference therebetween.

The manufacturing method of the electronic apparatus in an embodiment of the invention includes the following steps. A first chip is provided, wherein the first chip includes a first non-volatile memory. The first chip is used to execute a process. A first process execution history corresponding to the process is stored in the first non-volatile memory. A second chip is provided, wherein the second chip includes a second non-volatile memory. The second chip is used to execute the process. A second process execution history corresponding to the process is stored in the second non-volatile memory. The first process execution history and the second process execution history are compared to obtain a difference therebetween. The chip that executes the process normally is installed to a PCBA (printed circuit board assembly) or a PCB (printed circuit board).

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate exemplary embodiments of the invention and, together with the description, serve to explain the principles of the invention.

FIG. 1 is a schematic diagram of a chip according to an embodiment of the invention.

FIG. 2 is a schematic diagram of a chip according to another embodiment of the invention.

FIG. 3 is a flowchart illustrating an operation method of a chip according to an embodiment of the invention.

FIG. 4 is a flowchart illustrating a manufacturing method of an electronic apparatus according to an embodiment of the invention.

### DESCRIPTION OF THE EMBODIMENTS

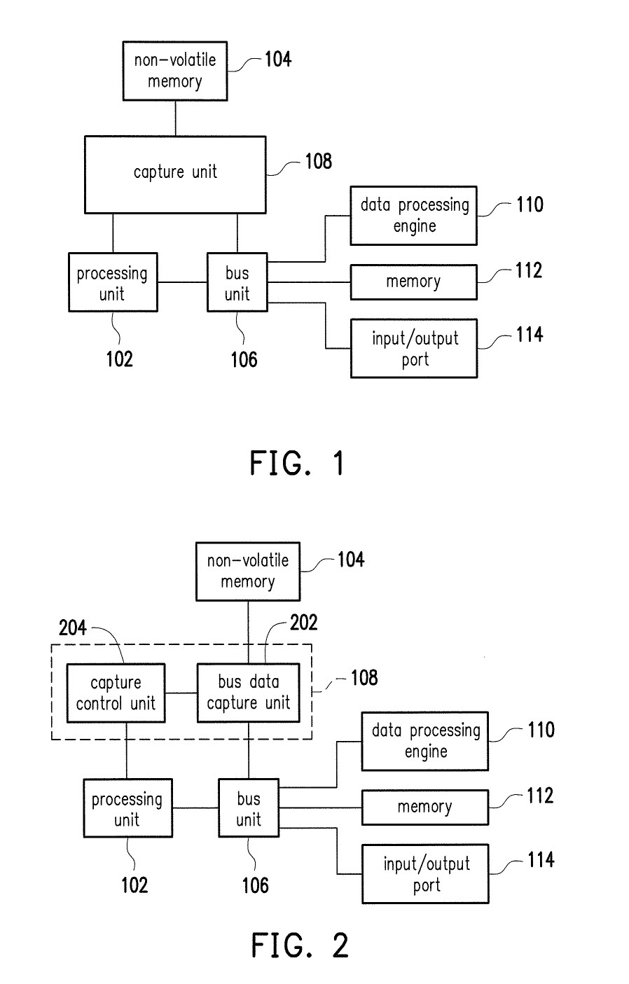

FIG. 1 is a schematic diagram of a chip according to an embodiment of the invention. Please refer to FIG. 1. The chip includes a processing unit 102, a non-volatile memory 104, a bus unit 106, and a capture unit 108. The processing unit 102 is coupled to the capture unit 108 and the bus unit 106, and the capture unit 108 is coupled to the non-volatile memory 104 and the bus unit 106. In addition, the bus unit 106 can be further connected to a data processing engine 110, a memory 112, and an input/output port 114 that is connected with peripheral equipment.

For example, the chip can be disposed on a motherboard of an electronic product, and the processing unit 102 can be configured to execute a process in firmware of the motherboard, so as to cause the chip to perform a corresponding operation. For instance, the processing unit 102 controls the data processing engine 110 through the bus unit 106 to process audio and video data, access data in the memory 112, or drive the peripheral equipment through the input/output port 114. The capture unit 108 can be configured to capture data from the bus unit 106, so as to capture a process execution history of the process executed by the processing unit 102 and store the process execution history in the non-volatile memory 104. Specifically, the capture unit 108 captures data from the bus unit 106 according to a signal, such as a control signal or a power signal. For example, the power signal can be a power on setting signal inputted via at least one pin of the chip, and the control signal can be a signal sent by the processing unit 102 for controlling the capture unit 108 to capture bus data.

Because the process may be complicated or take more time for execution, the non-volatile memory 104 may not be able to store the complete process execution history. In such a situation, the capture unit 108 may be controlled to capture and store only a specific segment of the process execution history, so as to avoid the problem of insufficient memory space of the non-volatile memory 104. For instance, when the power on setting signal is inputted via the pin of the chip, the capture unit 108 may be controlled to instantly start capturing and storing the process execution history; or, in order to avoid the problem that the non-volatile memory 104 does not have sufficient memory space for storing all the process execution history, the capture unit 108 may be controlled to capture and store the process execution history in a specific time segment or to capture and store a specific segment of the process execution history or a specific address of the process execution history after the power on setting signal is inputted via the pin of the chip. Moreover, in some embodiments, a method by which the capture unit 108 stores the process execution history may be as follows, for example: when the storage space of the non-volatile memory 104 runs out, the process execution history is overwritten in the non-volatile memory 104, or when the storage space of the non-volatile memory 104 runs out, storing of the process execution history in the non-volatile memory 104 is stopped.

Because the non-volatile memory 104 has the characteristic of retaining the stored data after power off, the process execution history stored in the non-volatile memory 104 by the capture unit 108 can still be accessed by other equipment (such as the test machine) after the chip is detached from the motherboard. Using this characteristic, the designer of a test process of the chip can compare the process execution history stored in the chip that does not execute the process normally and the process execution history stored in the chip that executes the process normally to obtain a difference therebetween, so as to find a blind spot in the test process of the original chip and thereby improve the coverage of the test process determining the quality of the chip. The non-volatile memory 104 is, for example, a flash memory, an EEPROM, or a memory that is capable of quick access and is accessible under a relatively low voltage and/or low current, such as a resistive random access memory (ReRam), a ferroelectric random access memory (FeRAM), a magnetic random access memory (MRAM), a phase-change random access memory (PRAM), and a conductive bridging random access memory (CBRAM).

In addition, whether the abnormal execution of the process is caused by the chip or the other components(e.g. memory) of the PCBA(printed circuit board assembly) can also be determined by comparing the process execution history stored in the chip that does not execute the process normally and the process execution history stored in the chip that executes the process normally, so as to clarify the responsibility of the product manufacturer and expedite solving the problem of the electronic product. For example, given that the chip and other components (e.g. memory) all function normally individually upon delivery, if a problem occurs when the chip and the other components are assembled in the PCBA or implemented in the PCBA, the aforementioned method can be utilized to determine which of the components cause the problem. If the history comparison result indicates that the abnormal history occurs during the access of the memory, it is determined that the problem results from the memory, not the chip.

For example, if a client uses chips that pass the test process on an electronic product and finds that the abnormal operation of the electronic product results from the chips (that is, the chips both pass the test process and function normally upon delivery, but one does not execute the process of the electronic product normally while the other one executes the process of the electronic product normally), the process execution histories that are stored when the chips execute the process of the electronic product of the client can be compared to find the blind spot in the test process, so as to identify the problem. In order to confirm that the abnormal operation of the electronic product results from the chips, different chips may be installed to the same electronic product by turns, or two different chips may be respectively installed to two electronic products of the same model, and the two electronic products may be controlled to execute the same operation, so as to prevent different operations from affecting the determination of the blind spot of the test. In such a situation, even if the circuit board in the client's product does not have an ICE (In-Circuit Emulator) interface, this method can still be used to identify the problem.

FIG. 2 is a schematic diagram of a chip according to another embodiment of the invention. Please refer to FIG. 2. More specifically, the capture unit 108 of the chip includes a bus data capture unit 202 and a capture control unit 204, for example, the capture control unit 204 can be coupled to the bus data capture unit 202 and the processing unit 102, and the bus data capture unit 202 is coupled to the non-volatile memory 104 and the bus unit 106. The bus data capture unit 202 is configured to capture the process execution history of the process from the bus unit 106 and store the process execution history in the non-volatile memory 104. The capture control unit 204 is configured for controlling the bus data capture unit 202 to capture the process execution history according to the aforementioned control signal or power signal, for example. The capture control unit 204 is implemented by a logic circuit, for example.

The capturing and storing of the process execution history performed by the capture unit 108 has been specified in the embodiment of FIG. 1. Those having ordinary skill in the art should be able to understand the operation of the chip of this embodiment based on the disclosure of the embodiment of FIG. 1. Therefore, details are not repeated here.

In the above embodiments, the chip is illustrated as an example for explaining the operation method. However, it should be noted that the operation method is applicable not only to the chip but also to various electronic apparatuses capable of executing the process.

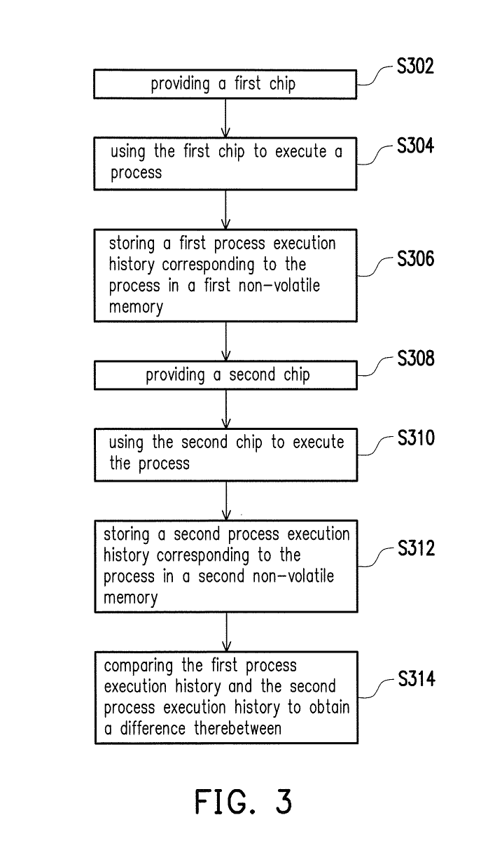

FIG. 3 is a flowchart illustrating an operation method, such as test method of a chip according to an embodiment of the invention. Please refer to FIG. 3. Based on the above, the operation method of the chip includes the following steps. First, a first chip is provided (Step S302), and the first chip includes a first non-volatile memory. Next, the first chip is used to execute a process (Step S304), and the process can be from firmware or software of the motherboard of the electronic product, or from firmware or software of other storage devices, for example. In addition, the process is bug-free upon verification. That is, if a problem occurs when the chip executes the process, a code corresponding to the process may be excluded from a debug process. Then, a first process execution history corresponding to the process is stored in the first non-volatile memory (Step S306). Thereafter, a second chip is provided (Step S308), and the second chip includes a second non-volatile memory. In this embodiment, the first chip executes the process normally while the second chip does not execute the process normally. Next, the second chip is used to execute the process (Step S310). Following that, a second process execution history corresponding to the process is stored in the second non-volatile memory (Step S312). Finally, the first process execution history and the second process execution history are compared to obtain a difference therebetween (Step S314). Accordingly, the test process of the chip can be amended, or the responsibility of the product manufacturer can be clarified according to the difference between the first process execution history and the second process execution history. Specifically, the difference between the first process execution history and the second process execution history may refer to a difference between the final results of the first chip and the second chip executing the process, or a difference in the sequence of appearance of intermediate results in the case of the same final results.

In order to avoid the problem that the first non-volatile memory and the second non-volatile memory have insufficient memory space, Step S306 and Step S312 may be performed to store only a specific segment of the first process execution history and the second process execution history (the specific segment may be a segment where an error is likely to occur, for example), or overwrite the first non-volatile memory and the second non-volatile memory until the segment where the error occurs is found. Moreover, in some embodiments, Steps S302-S306 and Steps S308-S312 may be performed at the same time. That is, two chips are respectively installed to two electronic products of the same model, and the two chips execute completely the same operation.

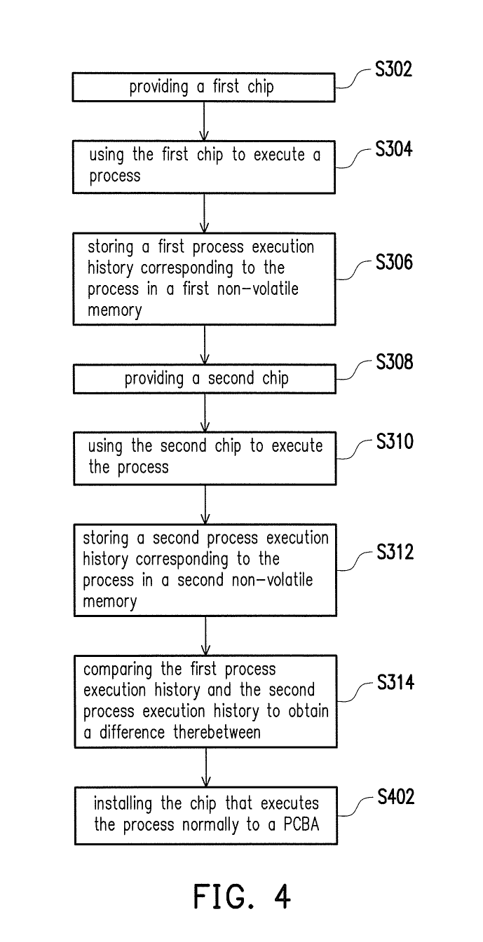

FIG. 4 is a flowchart illustrating a manufacturing method of an electronic apparatus according to an embodiment of the invention. Please refer to FIG. 4. A difference between this embodiment and the embodiment of FIG. 3 is that: this embodiment further includes Step S402 for installing the chip that executes the process normally to the PCBA (printed circuit board assembly) or a PCB (printed circuit board), so as to manufacture the electronic apparatus using the chip based on the aforementioned operation method to further improve production yield of the electronic apparatus.

To sum up, in the embodiments of the invention, the process execution histories of the process are stored in the non-volatile memory as records of execution of the chip that executes the process normally and the chip that does not execute the process normally, and by comparing the two process execution histories, the blind spot in the previous test process can be found to improve the test process and increase the coverage of determining the quality of the chips through the test process, or clarify the responsibility of the product manufacturer to solve the problem quickly.

What is claimed is:

1. A chip, comprising:
a processing unit configured to execute a process;
a non-volatile memory;
a bus unit coupled to the processing unit; and
a capture unit coupled to the non-volatile memory, the processing unit, and the bus unit, and configured to capture a process execution history of the process from the bus unit and store the process execution history in the non-volatile memory.

2. The chip according to claim 1, wherein the capture unit comprises:
a bus data capture unit coupled to the non-volatile memory and the bus unit; and
a capture control unit coupled to the processing unit and the bus data capture unit, and configured to control the bus data capture unit to capture the process execution history and store the process execution history in the non-volatile memory according to a signal.

3. The chip according to claim 2, wherein the signal is a power on setting signal or a control signal, wherein the control signal is sent by the processing unit.

4. The chip according to claim 1, wherein the capture unit further captures a specific segment of the process execution history and stores the specific segment of the process execution history in the non-volatile memory.

5. The chip according to claim 1, wherein the capture unit continues overwriting the process execution history in the non-volatile memory when storage space of the non-volatile memory runs out.

6. The chip according to claim 1, wherein the capture unit stops storing the process execution history in the non-volatile memory when storage space of the non-volatile memory runs out.

7. An operation method, comprising:
providing a first apparatus which comprises a first non-volatile memory;
executing a process by the first apparatus;
storing a first process execution history corresponding to the process in the first non-volatile memory;
providing a second apparatus which comprises a second non-volatile memory;
executing the process by the second apparatus;
storing a second process execution history corresponding to the process in the second non-volatile memory; and
comparing the first process execution history and the second process execution history to obtain a difference therebetween.

8. The operation method according to claim 7, further comprising:
amending a test process of the first apparatus or the second apparatus according to the difference between the first process execution history and the second process execution history.

9. The operation method according to claim 7, further comprising:
determining responsibility of a product manufacturer according to the difference between the first process execution history and the second process execution history.

10. The operation method according to claim 7, wherein the first apparatus is a chip or an electronic apparatus, and the second apparatus is a chip or an electronic apparatus.

11. The operation method according to claim 7, wherein the first apparatus and the second apparatus respectively comprise a PCBA (printed circuit board assembly) including a component and a chip, and the operation method of the chip further comprises:
determining whether the chip or the component causes abnormal execution of the process according to the difference between the first process execution history and the second process execution history.

12. The operation method according to claim 7, wherein the first apparatus is capable of executing the process normally, and the second apparatus is not capable of executing the process normally.

13. The operation method according to claim 7, wherein the process is bug-free.

14. The operation method according to claim 7, wherein the step of storing the first process execution history and the second process execution history comprises:
storing a specific segment of the first process execution history and the second process execution history.

15. A manufacturing method of an electronic apparatus, comprising:
providing a first chip which comprises a first non-volatile memory;
executing a process by the first chip;
storing a first process execution history corresponding to the process in the first non-volatile memory;
providing a second chip which comprises a second non-volatile memory;
executing the process by the second chip;
storing a second process execution history corresponding to the process in the second non-volatile memory;
comparing the first process execution history and the second process execution history to obtain a difference therebetween; and
installing the chip that executes the process normally to a PCBA (printed circuit board assembly) or a PCB.

16. The manufacturing method according to claim 15, further comprising:
amending a test process of the chip according to the difference between the first process execution history and the second process execution history.

17. The manufacturing method according to claim 15, further comprising:
determining responsibility of a product manufacturer according to the difference between the first process execution history and the second process execution history.

18. The manufacturing method according to claim 15, further comprising:
determining whether the first chip, the second chip or a component assembled or implemented in the PCBA (printed circuit board assembly) causes abnormal execution of the process according to the difference between the first process execution history and the second process execution history.

19. The manufacturing method according to claim 15, wherein the first chip is capable of executing the process normally, and the second chip is not capable of executing the process normally.

20. The manufacturing method according to claim 15, wherein the step of storing the first process execution history and the second process execution history comprises:
storing a specific segment of the first process execution history and the second process execution history.
